(19) United States
(12) Patent Application Publication
(10) Pub. No.: US 2021/0138606 A1
(43) Pub. Date: May 13, 2021

(54) SUBSTRATE HOLDING APPARATUS AND METHOD OF MANUFACTURING A DRIVE RING

(71) Applicant: EBARA CORPORATION, Tokyo (JP)

(72) Inventors: Keisuke NAMIKI, Tokyo (JP); Makoto FUKUSHIMA, Tokyo (JP); Osamu NABEYA, Tokyo (JP)

(21) Appl. No.: 16/980,995

(22) PCT Filed: Feb. 20, 2019
(86) PCT No.: PCT/JP2019/006313

§ 371 Date: Sep. 15, 2020

(30) Foreign Application Priority Data
Mar. 27, 2018 (JP) 2018-059670

(51) Int. Cl. B24B 37/32; B24B 37/04; B24B 37/20; H01L 21/304

(52) U.S. Cl. CPC B24B 37/32; H01L 21/304; B24B 37/20; B24B 37/04

(57) ABSTRACT

The present invention relates to a substrate holding apparatus used to polish a surface of the substrate by pressing the substrate against a polishing tool, such as a polishing pad. Further, the present invention relates to a method of manufacturing a drive ring used for the substrate holding apparatus. A substrate holding apparatus (1) includes a polishing head body (10), a drive ring (81) disposed below the polishing head body (10), and a retainer ring (40) fixed to the drive ring (81). The drive ring (81) has an annular contact surface (81a) that contacts the retainer ring (40). A flatness in the circumferential direction of the contact surface (81a) is 4.6 μm or less. The flatness represents a difference in a height between the highest position and the lowest position of the contact surface (81a).

### TECHNICAL FIELD

The present invention relates to a substrate holding apparatus for holding a substrate, such as a wafer, and more particularly to a substrate holding apparatus used to polish a surface of the substrate by pressing the substrate against a polishing tool, such as a polishing pad. Further, the present invention relates to a method of manufacturing a drive ring used in the substrate holding apparatus.

### BACKGROUND ART

In fabrication processes of a semiconductor device, a polishing apparatus is widely used to polish a surface of a wafer. The polishing apparatus of this type includes a polishing table supporting a polishing pad having a polishing surface, a substrate holding apparatus called a polishing head for holding the wafer, and a polishing liquid supply nozzle for supplying a polishing liquid onto the polishing surface.

The polishing apparatus polishes the wafer as follows. The polishing table is rotated together with the polishing pad, while the polishing liquid is supplied from the polishing liquid supply nozzle onto the polishing surface. The wafer is held by the substrate holding apparatus, and the wafer is rotated about its axis. In this state, the substrate holding apparatus presses the surface of the wafer against the polishing surface of the polishing pad so that the surface of the wafer is placed in sliding contact with the polishing surface in the presence of the polishing liquid. The surface of the wafer is planarized by a mechanical action of abrasive grains contained in the polishing liquid and a chemical action of the polishing liquid. Such polishing apparatus is called a CMP (chemical mechanical polishing) apparatus.

During polishing of the wafer, a frictional force acts on the wafer, because the surface of the wafer is in sliding contact with the rotating polishing pad. Therefore, in order to prevent the wafer from disengaging from the substrate holding apparatus during polishing of the wafer, the substrate holding apparatus includes a retainer ring. This retainer ring is arranged so as to surround the wafer, and is configured to press the polishing pad outside the wafer. The substrate holding apparatus further includes a drive ring for transmitting a torque to the retainer ring, and the retainer ring is fixed to the drive ring.

### CITATION LIST

### Patent Literature

Patent document 1: Japanese laid-open patent publication No. 2017-74639

### SUMMARY OF INVENTION

### Technical Problem

In addition to a role of preventing the wafer from disengaging from the substrate holding apparatus during polishing of the wafer, the retainer ring also has a role of controlling a polishing rate of a periphery of the wafer by controlling a rebound amount of the polishing pad. However, if a pressure applied from the retainer ring to the polishing pad is non-uniform in a circumferential direction, a repulsive force of the polishing pad applied to the wafer also becomes non-uniform in the circumferential direction depending on the non-uniform pressure. This non-uniformity of the pressure applied from the retainer ring to the polishing pad in the circumferential direction is one of factors causing variation in a polishing rate in the circumferential direction of the wafer.

Therefore, it is an object of the present invention to provide a substrate holding apparatus which can suppress a variation in polishing rate in a circumferential direction of a substrate, such as a wafer. Further, another object of the present invention is to provide a method of manufacturing a drive ring used in such a substrate holding apparatus.

### Solution to Problem

In an embodiment, there is provided a substrate holding apparatus comprising: a polishing head body; a drive ring disposed below the polishing head body; and a retainer ring fixed to the drive ring, wherein the drive ring has an annular contact surface that contacts the retainer ring, the contact surface has a flatness of not more than 4.6 μm in a circumferential direction of the contact surface, and the flatness represents a difference in a height between a highest position and a lowest position of the contact surface.

In an embodiment, an inner area of the contact surface has a flatness of not more than 4.6 μm in the circumferential direction of the contact surface, and the inner area is an area including an innermost edge of the contact surface.

In an embodiment, an outer area of the contact surface has a flatness of not more than 4.6 μm in the circumferential direction of the contact surface, and the outer area is an area including an outermost edge of the contact surface.

In an embodiment, an intermediate area of the contact surface has a flatness of not more than 4.6 μm in the circumferential direction of the contact surface, and the intermediate area is located radially outwardly of an innermost edge of the contact surface and radially inwardly of an outermost edge of the contact surface.

In an embodiment, the substrate holding apparatus further comprising reinforcing pins inserted into the retainer ring and fixed to a lower portion of the drive ring, the reinforcing pins being arranged apart from each other along the circumferential direction.

In an embodiment, the substrate holding apparatus further comprises spherical bearing configured to tiltably support the drive ring and the retainer ring.

In an embodiment, a rigidity of the drive ring is greater than a rigidity of the retainer ring.

In an embodiment, there is provided a method of manufacturing a drive ring used in a substrate holding apparatus configured to press a substrate against a polishing pad, comprising: polishing a contact surface of the drive ring such that a flatness of the contact surface in a circumferential direction is not more than 4.6 μm, wherein the contact surface is an annular contact surface that contacts the retainer ring used in the substrate holding apparatus, and the flatness represents a difference in a height between a highest position and a lowest position of the contact surface.

In an embodiment, polishing the contact surface such that the flatness is not more than 4.6 μm comprises: grinding the contact surface of the drive ring; and then polishing the contact surface until the flatness becomes 4.6 μm or less by relatively moving the drive ring and a polishing tool while pressing the contact surface against the polishing tool in the presence of abrasive grains between the drive ring and the polishing tool.

### Advantageous Effects of Invention

The contact surface of the drive ring is as flat as 4.6 μm, so that non-uniformity of a pressure in the circumferential direction applied from the retainer ring to the polishing pad can be suppressed. As a result, the substrate holding apparatus can suppress a variation in a polishing rate in a circumferential direction of the substrate.

### BRIEF DESCRIPTION OF DRAWINGS

FIG. 1 is a schematic view showing a polishing apparatus including a substrate holding apparatus according to an embodiment of the present invention;

FIG. 2 is a view showing a detailed structure of the polishing apparatus;

FIG. 3 is a cross-sectional view of a polishing head shown in FIG. 1;

FIG. 4 is a cross-sectional view of a drive ring and a retainer ring;

FIG. 5 is a bottom view of the drive ring;

FIG. 6 is a side view schematically showing a state in which the retainer ring presses a polishing surface of a polishing pad;

FIG. 7A is a cross-sectional view taken along line A-A in FIG. 6;

FIG. 7B is a cross-sectional view taken along line B-B in FIG. 6;

FIG. 8A is a diagram showing an example of a variation in height in a circumferential direction of a contact surface of a drive ring;

FIG. 8B is a diagram showing a polishing rate of a periphery of a wafer when the drive ring of FIG. 8A is used;

FIG. 9A is a diagram showing an example of a variation in height in a circumferential direction of a contact surface of the drive ring in this embodiment;

FIG. 9B is a diagram showing a polishing rate of a periphery of a wafer in this embodiment;

FIG. 10 is a graph showing a relationship between a flatness in the circumferential direction of the contact surface of the drive ring and the variation in the polishing rate in the circumferential direction of the periphery of the wafer;

FIG. 11 is a flowchart describing a method of manufacturing the drive ring;

FIG. 12 is a cross-sectional view of another embodiment of the polishing head;

FIG. 13 is a plan view showing the drive ring and a coupling member;

FIG. 14 is a view of a spherical bearing;

FIG. 15A is a view showing the manner in which the coupling member is vertically moved relative to the spherical bearing;

FIG. 15B is a view showing the manner in which the coupling member tilts together with an inner bearing ring;

FIG. 15C is a view showing the manner in which the coupling member tilts together with an inner bearing ring;

FIG. 16 is an enlarged cross-sectional view of another example of the spherical bearing;

FIG. 17A is a view showing the manner in which the coupling member is vertically moved relative to the spherical bearing;

FIG. 17B is a view showing the manner in which the coupling member tilts together with an intermediate bearing ring;

FIG. 17C is a view showing the manner in which the coupling member tilts together with an intermediate bearing ring;

FIG. 18A is a cross-sectional view of the drive ring and the retainer ring shown in FIG. 12; and

FIG. 18B is a bottom view showing a part of the drive ring shown in FIG. 12.

### DESCRIPTION OF EMBODIMENTS

Embodiments of the present invention will be described below with reference to the drawings. FIG. 1 is a schematic view showing a polishing apparatus including a substrate holding apparatus according to an embodiment of the present invention. As shown in FIG. 1, the polishing apparatus includes a polishing head 1 as a substrate holding apparatus for holding and rotating a wafer W, which is an example of a substrate, a polishing table 3 for supporting a polishing pad 2 thereon, a polishing liquid supply nozzle 5 for supplying a polishing liquid (e.g., slurry) onto the polishing pad 2, and a film-thickness sensor 7 for obtaining a film thickness signal that varies according to a film thickness of the wafer W. The film-thickness sensor 7 is disposed in the polishing table 3 and generates the film thickness signal at multiple regions, including a central region, of the wafer W every time the polishing table 3 makes one revolution. Examples of the film-thickness sensor 7 include an optical sensor and an eddy current sensor.

The polishing head 1 is configured to be able to hold the wafer W on its lower surface by vacuum suction. The polishing head 1 and the polishing table 3 rotate in the same direction as indicated by arrows. In this state, the polishing head 1 presses the wafer W against a polishing surface 2a of the polishing pad 2. The polishing liquid is supplied from the polishing liquid supply nozzle 5 onto the polishing pad 2, so that the wafer W is polished by sliding contact with the polishing pad 2 in the presence of the polishing liquid. During polishing of the wafer W, the film-thickness sensor 7 rotates together with the polishing table 3 and generates the film thickness signal while sweeping across a surface of the wafer W as shown by a symbol A. This film thickness signal is an index value indicating the film thickness directly or indirectly, and varies in accordance with a decrease in the film thickness of the wafer W. The film-thickness sensor 7 is coupled to a polishing controller 9 so that the film thickness signal is transmitted to the polishing controller 9. This polishing controller 9 is configured to terminate polishing of the wafer W when the film thickness of the wafer W, which is indicated by the film thickness signal, has reached a predetermined target value.

FIG. 2 is a view showing a detailed structure of the polishing apparatus. The polishing table 3 is coupled to a motor 13 through a table shaft 3a and is rotated about the table shaft 3a by the motor 13 which is disposed below the polishing table 3. The polishing pad 2 is attached to an upper surface of the polishing table 3. An upper surface of the polishing pad 2 provides the polishing surface 2a for polishing the wafer W. When the polishing table 3 is rotated by the motor 13, the polishing surface 2a moves relative to the polishing head 1. Therefore, the motor 13 serves as a polishing surface moving mechanism for moving the polishing surface 2a horizontally.

The polishing head 1 is coupled to a polishing head shaft 11, which is movable vertically relative to a polishing head oscillation arm 16 by a vertically moving mechanism 27. A vertical movement and positioning of the polishing head 1 in its entirety relative to the polishing head oscillation arm 16 are achieved by the vertical movement of the polishing head shaft 11. A rotary joint 25 is mounted to an upper end of the polishing head shaft 11.

The vertically moving mechanism 27 for elevating and lowering the polishing head shaft 11 and the polishing head 1 includes a bridge 28 for rotatably supporting the polishing head shaft 11 through a bearing 26, a ball screw 32 mounted to the bridge 28, a support base 29 supported by pillars 30, and a servomotor 38 mounted to the support base 29. The support base 29 for supporting the servomotor 38 is secured to the polishing head oscillation arm 16 through the pillars 30.

The ball screw 32 has a screw shaft 32a coupled to the servomotor 38 and a nut 32b which is in engagement with the screw shaft 32a. The polishing head shaft 11 is configured to move vertically together with the bridge 28. Therefore, when the servomotor 38 is set in motion, the bridge 28 moves vertically through the ball screw 32 to cause the polishing head shaft 11 and the polishing head 1 to move vertically.

The polishing head shaft 11 is further coupled to a rotary cylinder 12 through a key (not shown). This rotary cylinder 12 has a timing pulley 14 on its outer circumferential surface. A polishing head motor 18 is secured to the polishing head oscillation arm 16, and a timing pulley 20 is mounted to the polishing head motor 18. The timing pulley 14 is coupled to the timing pulley 20 through a timing belt 19. With these configurations, rotation of the polishing head motor 18 is transmitted to the rotary cylinder 12 and the polishing head shaft 11 through the timing pulley 20, the timing belt 19, and the timing pulley 14 to rotate the rotary cylinder 12 and the polishing head shaft 11 in unison, thus rotating the polishing head 1 about its own axis. The polishing head motor 18, the timing pulley 20, the timing belt 19, and the timing pulley 14 constitute a rotating mechanism for rotating the polishing head 1 about its own axis. The polishing head oscillation arm 16 is supported by a support shaft 21 which is rotatably supported by a frame (not shown). The polishing head 1 is configured to hold a substrate, such as the wafer W, on its lower surface. The polishing head oscillation arm 16 is configured to be able to pivot around the support shaft 21.

The wafer W is polished as follows. The polishing head 1 and the polishing table 3 are rotated individually, and the polishing liquid is supplied onto the polishing pad 2 from the polishing liquid supply nozzle 5 provided above the polishing table 3. The polishing head 1 holding the wafer W on its lower surface is moved from a receiving position of the wafer W to a position above the polishing table 3 by the rotation of the polishing head oscillation arm 16. Then, the polishing head 1 is lowered and the wafer W is pressed against the polishing surface 2a of the polishing pad 2. The wafer W is placed in sliding contact with the polishing surface 2a in the presence of the polishing liquid. The surface of the wafer W is planarized by a mechanical action of abrasive grains contained in the polishing liquid and a chemical action of the polishing liquid.

Next, the polishing head 1 constituting the substrate holding apparatus will be described below. FIG. 3 is a cross-sectional view of the polishing head 1 shown in FIG. 1. As shown in FIG. 3, the polishing head 1 includes an elastic membrane 45 for pressing the wafer W against the polishing surface 2a of the polishing pad 2, a polishing head body 10 that holds the elastic membrane 45, and an annular drive ring 81 disposed below the polishing head body 10, and an annular retainer ring 40 fixed to the lower surface of the drive ring 81. The elastic membrane 45 is attached to the lower portion of the polishing head body 10. The polishing head body 10 is fixed to an end of the polishing head shaft 11. The polishing head body 10, the elastic membrane 45, the drive ring 81, and the retainer ring 40 are configured to rotate together by the rotation of the polishing head shaft 11. The retainer ring 40 and the drive ring 81 are configured to be vertically movable relative to the polishing head body 10. The polishing head body 10 is made of resin, such as engineering plastic (e.g., PEEK).

Four pressure chambers 50, 51, 52, and 53 are provided between the elastic membrane 45 and the polishing head body 10. The pressure chambers 50, 51, 52, and 53 are formed by the elastic membrane 45 and the polishing head body 10. The central pressure chamber 50 has a circular shape, and the other pressure chambers 51, 52, and 53 have an annular shape. These pressure chambers 50, 51, 52, and 53 are in a concentric arrangement.

Gas delivery lines F1, F2, F3, and F4 are coupled to the pressure chambers 50, 51, 52, and 53, respectively. One end of each of the gas delivery lines F1, F2, F3, and F4 is coupled to a compressed-gas supply source (not shown), which is provided as one of utilities in a factory in which the polishing apparatus is installed. A compressed gas, such as compressed air, is supplied into the pressure chambers 50, 51, 52, and 53 through the gas delivery lines F1, F2, F3, and F4, respectively.

The gas delivery line F3, which communicates with the pressure chamber 52, is coupled to a vacuum line (not shown), so that a vacuum can be formed in the pressure chamber 52. The elastic membrane 45 has an opening in a portion that forms the pressure chamber 52, so that the wafer W can be held by the polishing head 1 via vacuum suction by producing a vacuum in the pressure chamber 52. Further, the wafer W can be released from the polishing head 1 by supplying the compressed gas into the pressure chamber 52. The elastic membrane 45 is made of a highly strong and durable rubber material, such as ethylene propylene rubber (EPDM), polyurethane rubber, silicone rubber, or the like.

The retainer ring 40 is arranged around the elastic membrane 45. The retainer ring 40 is an annular member that contacts the polishing surface 2a of the polishing pad 2. The retainer ring 40 is arranged so as to surround a peripheral edge of the wafer W, and prevents the wafer W from being ejected from the polishing head 1 during polishing of the wafer W.

The drive ring 81 has an upper portion which is coupled to an annular retainer ring pressing mechanism 60. The retainer ring pressing mechanism 60 is configured to exert a downward load on the entirety of an upper surface 40b of the retainer ring 40 via the drive ring 81 to thereby press a lower surface 40a of the retainer ring 40 against the polishing surface 2a of the polishing pad 2.

The retainer ring pressing mechanism 60 includes an annular piston 61 secured to an upper portion of the drive ring 81, and an annular rolling diaphragm 62 coupled to an upper surface of the piston 61. A retainer ring pressure chamber 63 is formed inside the rolling diaphragm 62. This retainer ring pressure chamber 63 is coupled to the compressed-gas supply source through a gas delivery line F5. The compressed gas is supplied into the retainer ring pressure chamber 63 through the gas delivery line F5.

When the compressed gas is supplied from the compressed-gas supply source into the retainer ring pressure chamber 63, the rolling diaphragm 62 pushes down the piston 61, the piston 61 pushes down the drive ring 81, and the drive ring 81 pushes down the entire retainer ring 40. In this manner, the retainer ring pressing mechanism 60 presses the lower surface 40a of the retainer ring 40 against the polishing surface 2a of the polishing pad 2.

The drive ring 81 is removably coupled to the retainer ring pressing mechanism 60. More specifically, the piston 61 and the drive ring 81 are mechanically coupled by a fastening member or the like. The fastening member may be a resin fixing member, a magnet, or a metal bolt.

The gas delivery lines F1, F2, F3, F4, and F5 extend via the rotary joint 25 attached to the polishing head shaft 11. The gas delivery lines F1, F2, F3, F4, and F5, communicating with the pressure chambers 50, 51, 52, 53, and the retainer ring pressure chamber 63, respectively, are provided with pressure regulators R1, R2, R3, R4, and R5, respectively. The compressed gas from the compressed-gas supply source is supplied through the pressure regulators R1 to R5 into the pressure chambers 50 to 53 and the retainer ring pressure chamber 63, respectively and independently. The pressure regulators R1 to R5 are configured to regulate the pressures of the compressed gases in the pressure chambers 50 to 53 and the retainer ring pressure chamber 63.

The pressure regulators R1 to R5 can change independently the pressures in the pressure chambers 50 to 53 and the retainer ring pressure chamber 63 to thereby independently adjust the polishing pressures against corresponding four areas of the wafer W, i.e., a central portion; an inner intermediate portion; an outer intermediate portion; and an edge portion, and a pressing force of the retainer ring 40 against the polishing pad 2. The gas delivery lines F1, F2, F3, F4 and F5 are coupled to vent valves (not shown), respectively, so that the pressure chambers 50 to 53 and the retainer ring pressure chamber 63 can be vented to the atmosphere. The elastic membrane 45 in this embodiment defines the four pressure chambers 50 to 53, while, in one embodiment, the elastic membrane 45 may define less than four pressure chambers or more than four pressure chambers.

FIG. 4 is a cross-sectional view of the drive ring 81 and the retainer ring 40, and FIG. 5 is a bottom view of the drive ring 81. As shown in FIGS. 4 and 5, the drive ring 81 has an annular contact surface 81a that contacts the retainer ring 40. In this embodiment, a lower surface of the drive ring 81 forms the contact surface 81a. The upper surface 40b of the retainer ring 40 is fixed to the lower surface (the contact surface 81a) of the drive ring 81. More specifically, a plurality of threaded holes 40c into which a plurality of bolts 84 are respectively screwed are formed in the upper surface of the retainer ring 40. A plurality of through-holes 81f through which the bolts 84 extend are formed in the drive ring 81. In FIG. 4, only one through-hole 81f, one threaded hole 40c, and one bolt 84 are depicted. The bolts 84 are screwed through the through-holes 81f into the threaded holes 40c, respectively, so that the upper surface 40b of the retainer ring 40 is fixed to the lower surface (the contact surface 81a) of the drive ring 81.

The contact surface 81a of the drive ring 81 is flat in a circumferential direction of the drive ring 81. More specifically, a flatness in the circumferential direction of the contact surface 81a is not more than 4.6 μm. In this specification, the flatness is defined as a difference in height between the highest position and the lowest position of the contact surface 81a. In this embodiment, the contact surface 81a has three areas, and the flatness of each area in the circumferential direction is not more than 4.6 μm. The three areas are an inner area 81b, an outer area 81c, and an intermediate area 81d. As shown in FIG. 5, The inner area 81b is an area including an innermost edge of the contact surface 81a. The outer area 81c is an area including an outermost edge of the contact surface 81a. The intermediate area 81d is an area located between the inner area 81b and the outer area 81c. Specifically, the intermediate area 81d is located radially outwardly of the innermost edge of the contact surface 81a, and located radially inwardly of the outermost edge of the contact surface 81a. In this embodiment, the inner area 81b, the intermediate area 81d, and the outer area 81c have the same width, but may have different widths.

In this embodiment, the flatness in the circumferential direction of the contact surface 81a is 4.6 μm or less over the entire contact surface 81a (i.e. in the inner area 81b, the intermediate area 81d, and the outer area 81c). In one embodiment, the flatness of the contact surface 81a in its circumferential direction may be 4.6 μm or less in at least one of the inner area 81b, the intermediate area 81d, and the outer area 81c.

FIG. 6 is a side view schematically showing a state in which the retainer ring 40 presses the polishing surface 2a of the polishing pad 2. A rigidity of the drive ring 81 is greater than a rigidity of the retainer ring 40. Therefore, as shown in FIG. 6, when the retainer ring 40 is fixed to the drive ring 81, shapes of the upper surface 40b and the lower surface 40a of the retainer ring 40 follow a shape of the contact surface 81a of the drive ring 81. Examples of material of the drive ring 81 may include stainless steel and ceramic. An example of material of the retainer ring 40 may include poly phenylene sulfide (PPS) resin.

FIG. 7A is a cross-sectional view taken along line A-A in FIG. 6. FIG. 7B is a cross-sectional view taken along line B-B in FIG. 6. A pressure applied from the retainer ring 40 to the polishing surface 2a of the polishing pad 2 may change depending on the shape of the contact surface 81a of the drive ring 81. Specifically, as shown in FIGS. 7A and 7B, the lower the position of the contact surface 81a, the lower the position of the retainer ring 40, resulting in an increase in the pressure applied from the retainer ring 40 to the polishing surface 2a of the polishing pad 2 (i.e., a pushing amount of the polishing pad 2).

As shown in FIGS. 7A and 7B, when the retainer ring 40 is pressed against the polishing pad 2, the polishing surface 2a of the polishing pad 2 is dented and other portion of the polishing surface 2a is raised upward. The raised portion of the polishing surface 2a applies an upward force to a periphery of the wafer W. In the following descriptions, this upward force will be referred to as a repulsive force. The repulsive force of the polishing pad 2 applied to the wafer W depends on the pressure applied to the polishing pad 2 from the retainer ring 40. Therefore, the shape of the contact surface 81a of the drive ring 81 affects the repulsive force against the periphery of the wafer W.

The pressure applied from the retainer ring 40 to the polishing pad 2 shown in FIG. 7A is larger than the pressure applied from the retainer ring 40 to the polishing pad 2 shown in FIG. 7B, and the repulsive force of the polishing pad 2 applied to the periphery of the wafer W shown in FIG. 7A is larger than the repulsive force of the polishing pad 2 applied to the periphery of the wafer W shown in FIG. 7B. When the repulsive force of the polishing pad 2 against the periphery of the wafer W increases, a polishing rate of that portion of the wafer W increases. When the repulsive force of the polishing pad 2 against the periphery of the wafer W decreases, the polishing rate of that portion of the wafer W decreases. Therefore, the polishing rate of the periphery of the wafer W may change depending on the shape of the contact surface 81a of the drive ring 81.

FIG. 8A is a diagram showing an example of a variation in height in a circumferential direction of a contact surface of a drive ring. FIG. 8B is a diagram showing a polishing rate of a periphery of a wafer when the drive ring of FIG. 8A is used. Vertical axis of FIG. 8A represents height of the contact surface of the drive ring from a virtual reference plane. Horizontal axis of FIG. 8A represents angle from a reference point on the contact surface of the drive ring. The flatness of the contact surface of the drive ring in the circumferential direction in FIG. 8A is 14 μm. Vertical axis of FIG. 8B represents polishing rate of the periphery of the wafer, and horizontal axis of FIG. 8B represents angle from a reference point on the periphery of the wafer. The reference point in FIG. 8A and the reference point in FIG. 8B coincide in a radial direction.

FIG. 9A is a diagram showing an example of a variation in height in the circumferential direction of the contact surface 81a of the drive ring 81 according to the embodiment. FIG. 9B is a diagram showing the polishing rate of the periphery of the wafer W according to the embodiment. Vertical axis of FIG. 9A represents height of the contact surface 81a of the drive ring 81 from a virtual reference plane. Horizontal axis of FIG. 9A represents angle from a reference point on the contact surface 81a of the drive ring 81. A flatness of the contact surface 81a of the drive ring 81 in the circumferential direction in FIG. 9A is not more than 4.6 μm. Vertical axis of FIG. 9B represents polishing rate of the periphery of the wafer W, and horizontal axis of FIG. 9B represents angle from a reference point on the periphery of the wafer W. The reference point in FIG. 9A and the reference point in FIG. 9B coincide in a radial direction.

As shown in FIGS. 8A, 8B, 9A, and 9B, a polishing rate of a periphery of a wafer may vary in a circumferential direction depending on a shape of a contact surface of a drive ring in a circumferential direction. Therefore, when the flatness of the contact surface of the drive ring in the circumferential direction is large, the variation in the polishing rate in the circumferential direction of the periphery of the wafer is large, and when the flatness of the contact surface of the drive ring in the circumferential direction is small, the variation in the polishing rate in the circumferential direction of the periphery of the wafer is small.

The upper limit of the flatness, 4.6 μm, is determined based on a magnitude of the variation in polishing rate in a periphery of a wafer. FIG. 10 is a graph showing a relationship between the flatness of the contact surface of the drive ring in the circumferential direction and the variation in the polishing rate in the circumferential direction of the periphery of the wafer. The wafer used in FIG. 10 is a blanket wafer for testing having a film, such as an oxide film, uniformly formed on an entire surface of a silicon wafer. Horizontal axis of FIG. 10 represents the flatness of the contact surface of the drive ring in the circumferential direction. Vertical axis of FIG. 10 represents magnitude of the variation in polishing rate in a circumferential direction of a periphery of the test wafer. More specifically, the value on the vertical axis in FIG. 10 is given by

$$\frac{1}{N} {\sum }_{i = 1}^{N} \frac{3 {σ}_{i}}{R {A}_{i}} \times 100 \%$$

where N is the number of wafers, σᵢ is a standard deviation of a polishing rate distributed in the circumferential direction of i-th wafer, and RAᵢ is an average of the polishing rate of the i-th wafer.

As shown in FIG. 10, the magnitude of the variation in the polishing rate hardly changes when the flatness of the contact surface of the drive ring in the circumferential direction is 4.6 μm or less. From these measurement results, the flatness of the contact surface 81a of the drive ring 81 in the circumferential direction was determined to be not more than 4.6 μm.

As described above, in this embodiment, the flatness of the contact surface 81a in the circumferential direction is 4.6 μm or less over the entire contact surface 81a (i.e., in the inner area 81b, the intermediate area 81d, and the outer area 81c shown in FIG. 5). As can be seen from FIGS. 7A and 7B, the polishing rate of the periphery of the wafer W is affected by a pressure of an inner portion of the retainer ring 40 against the polishing pad 2. Therefore, in one embodiment, the flatness in at least the inner area 81b in the circumferential direction is 4.6 μm or less.

The drive ring 81 is manufactured by polishing the contact surface 81a such that the flatness of the contact surface 81a in the circumferential direction is 4.6 μm or less. One embodiment of a method of manufacturing the drive ring 81 will be described with reference to a flowchart shown in FIG. 11. First, the contact surface 81a of the drive ring 81 is roughly ground by a grinding process (step 1). An example of such a grinding process may include lathe process.

Next, the contact surface 81a of the drive ring 81 is polished by a lapping apparatus for finish polishing until the flatness of the contact surface 81a in the circumferential direction becomes 4.6 μm or less (step 2). More specifically, in a state in which abrasive grains are present between the drive ring 81 and a polishing tool of the lapping apparatus, the contact surface 81a is polished by relatively moving the drive ring 81 and the polishing tool while pressing the contact surface 81a of the drive ring 81 against the polishing tool (step 2).

After the contact surface 81a is polished, the flatness of the contact surface 81a in the circumferential direction is measured (step 3). When the flatness is 4.6 μm or less, a series of manufacturing steps is completed. When the flatness is larger than 4.6 μm, the step 2 is repeated again to further polish the contact surface 81a.

Measuring of the flatness of the contact surface 81a in the circumferential direction is performed in each circumferential direction at three or more positions in the radial direction. Such measuring is performed at predetermined intervals on each circumference. The interval is determined based on the intervals between the plurality of bolts 84 that fix the retainer ring 40 and the drive ring 81.

In one embodiment, regardless of the radial position of the contact surface 81a, the flatness in the circumferential direction may be 4.6 μm or less at any radial position. Furthermore, in one embodiment, the flatness of one predetermined circumference of the contact surface 81a may be 4.6 μm.

FIG. 12 is a cross-sectional view of another embodiment of the polishing head 1. Structures, which will not be described particularly in this embodiment, are identical to those of the embodiment described with reference to FIGS. 1 through 10, and repetitive descriptions thereof are omitted. The polishing head body 10 of this embodiment has a circular flange 41, a spacer 42 mounted to a lower surface of the flange 41, and a carrier 43 mounted to a lower surface of the spacer 42. The flange 41 is coupled to the polishing head shaft 11. The carrier 43 is coupled to the flange 41 via the spacer 42, so that the flange 41, the spacer 42, and the carrier 43 rotate and vertically move together. The polishing head body 10, which is constructed by the flange 41, the spacer 42, and the carrier 43, is made of resin, such as engineering plastic (e.g., PEEK). The flange 41 may be made of metal, such as SUS, aluminum, or the like.

The retainer ring 40 is coupled to a spherical bearing 85 through the drive ring 81 and a coupling member 75. The spherical bearing 85 is disposed radially inwardly of the retainer ring 40. FIG. 13 is a plan view showing the drive ring 81 and the coupling member 75. As shown in FIG. 13, the coupling member 75 includes a shaft portion 76 disposed centrally in the polishing head body 10, a hub 77 secured to the shaft portion 76, and a plurality of spokes 78 extending radially from the hub 77.

The spokes 78 have ends fixed to the hub 77, and have the other ends fixed to the drive ring 81. The hub 77, the spokes 78, and the drive ring 81 are formed integrally. Plural pairs of drive pins 80 and 80 are secured to the carrier 43. The drive pins 80 and 80 of each pair are arranged on both sides of each spoke 78. The rotation of the carrier 43 is transmitted to the drive ring 81 and the retainer ring 40 via the drive pins 80 and 80 to thereby rotate the polishing head body 10 and the retainer ring 40 together with each other.

As shown in FIG. 12, the shaft portion 76 extends in the vertical direction in the spherical bearing 85. As shown in FIG. 13, the carrier 43 has a plurality of radial grooves 43a in which the spokes 78 are disposed, respectively. Each spoke 78 is movable freely in the vertical direction in each groove 43a. The shaft portion 76 of the coupling member 75 is supported by the spherical bearing 85 such that the shaft portion 76 can move in the vertical direction. The spherical bearing 85 is located at the center of the polishing head body 10. With these configurations, the coupling member 75, and the drive ring 81 and the retainer ring 40, which are coupled to the coupling member 75, are thus vertically movable relative to the polishing head body 10. Further, the drive ring 81 and the retainer ring 40 are tiltably supported by the spherical bearing 85.

FIG. 14 is a view of the spherical bearing 85. The shaft portion 76 is secured to the hub 77 by a plurality of screws 79. The shaft portion 76 has a vertically extending through-hole 88 formed therein. This through-hole 88 acts as an air vent hole when the shaft portion 76 moves vertically relative to the spherical bearing 85. Therefore, the retainer ring 40 can move smoothly in the vertical direction relative to the polishing head body 10.

The spherical bearing 85 includes an annular inner bearing ring 101, and an annular outer bearing ring 102 which slidably supports an outer circumferential surface of the inner bearing ring 101. The inner bearing ring 101 is coupled to the drive ring 81 and the retainer ring 40 through the coupling member 75. The outer bearing ring 102 is secured to a support member 103, which is secured to the carrier 43. The support member 103 is disposed in a recess 43b of the carrier 43.

The outer circumferential surface of the inner bearing ring 101 has a spherical shape whose upper and lower portions are cut off. A central point (fulcrum) 0 of this spherical shape is located at the center of the inner bearing ring 101. The outer bearing ring 102 has an inner circumferential surface which is a concave surface shaped so as to fit the outer circumferential surface of the inner bearing ring 101, so that the outer bearing ring 102 slidably supports the inner bearing ring 101. Therefore, the inner bearing ring 101 is tiltable in all directions (360°) relative to the outer bearing ring 102.

The inner bearing ring 101 has an inner circumferential surface which forms a through-hole 101a in which the shaft portion 76 is inserted. The shaft portion 76 is movable relative to the inner bearing ring 101 only in the vertical direction. Therefore, the retainer ring 40, which is coupled to the shaft portion 76, is not allowed to move laterally. Specifically, the retainer ring 40 is fixed in its lateral position (i.e., its horizontal position) by the spherical bearing 85. The spherical bearing 85 serves as a supporting mechanism capable of receiving the lateral force (i.e., the force in the radially outward direction of the wafer) applied from the wafer to the retainer ring 40 due to the friction between the wafer and the polishing pad 2 and capable of restricting the lateral movement of the retainer ring 40 (i.e., capable of fixing the horizontal position of the retainer ring 40) during polishing of the wafer.

FIG. 15A shows the manner in which the coupling member 75 is vertically moved relative to the spherical bearing 85. FIGS. 15B and 15C show the manner in which the coupling member 75 tilts together with the inner bearing ring 101. The retainer ring 40, which is coupled to the coupling member 75, is tiltable around the fulcrum O together with the inner bearing ring 101 and is vertically movable relative to the inner bearing ring 101.

FIG. 16 is an enlarged cross-sectional view of another example of the spherical bearing 85. As shown in FIG. 16, the spherical bearing 85 includes an intermediate bearing ring 91 coupled to the retainer ring 40 via the coupling member 75, an outer bearing ring 92 slidably supporting the intermediate bearing ring 91 from above, and an inner bearing ring 93 slidably supporting the intermediate bearing ring 91 from below. The intermediate bearing ring 91 is in the form of a partial spherical shell smaller than an upper half of a spherical shell. The intermediate bearing ring 91 is sandwiched between the outer bearing ring 92 and the inner bearing ring 93.

The outer bearing ring 92 is disposed in the recess 43b. The outer bearing ring 92 has a flange portion 92a on its outer circumferential surface. The flange portion 92a is secured to a step of the recess 43b by bolts (not shown), thereby securing the outer bearing ring 92 to the carrier 43 and applying pressure to the intermediate bearing ring 91 and the inner bearing ring 93. The inner bearing ring 93 is disposed on a bottom surface of the recess 43b. This inner bearing ring 93 supports the intermediate bearing ring 91 upwardly so as to form a gap between a lower surface of the intermediate bearing ring 91 and the bottom surface of the recess 43b.

The outer bearing ring 92 has an inner surface 92b, the intermediate bearing ring 91 has an outer surface 91a and an inner surface 91b, and the inner bearing ring 93 has an outer surface 93a. Each of these surfaces 92b, 91a, 91b, and 93a is an approximately hemispheric surface whose center is represented by a fulcrum O. The outer surface 91a of the intermediate bearing ring 91 slidably contacts the inner surface 92b of the outer bearing ring 92. The inner surface 91b of the intermediate bearing ring 91 slidably contacts the outer surface 93a of the inner bearing ring 93. The inner surface 92b (sliding contact surface) of the outer bearing ring 92, the outer surface 91a and the inner surface 91b (sliding contact surfaces) of the intermediate bearing ring 91, and the outer surface 93a (sliding contact surface) of the inner bearing ring 93 have a partial spherical shape smaller than an upper half of a spherical surface. With these configurations, the intermediate bearing ring 91 is tiltable in all directions through 360° relative to the outer bearing ring 92 and the inner bearing ring 93. The fulcrum O, which is the center of the tilting movement of the intermediate bearing ring 91, is located below the spherical bearing 85.

The outer bearing ring 92, the intermediate bearing ring 91, and the inner bearing ring 93 have respective through-holes 92c, 91c, and 93b formed therein in which the shaft portion 76 is inserted. There is a gap between the through-hole 92c of the outer bearing ring 92 and the shaft portion 76. Similarly, there is a gap between the through-hole 93b of the inner bearing ring 93 and the shaft portion 76. The through-hole 91c of the intermediate bearing ring 91 has a diameter smaller than those of the through-holes 92c and 93b of the outer bearing ring 92 and the inner bearing ring 93 such that the shaft portion 76 is movable relative to the intermediate bearing ring 91 only in the vertical direction. Therefore, the retainer ring 40, which is coupled to the shaft portion 76, is substantially not allowed to move laterally. Specifically, the retainer ring 40 is fixed in its lateral position (i.e., its horizontal position) by the spherical bearing 85.

FIG. 17A shows the manner in which the coupling member 75 is vertically moved relative to the spherical bearing 85, and FIGS. 17B and 17C show the manner in which the coupling member 75 tilts together with the intermediate bearing ring 91. As shown in FIGS. 17A through 17C, the retainer ring 40, which is coupled to the coupling member 75, is tiltable around the fulcrum O together with the intermediate bearing ring 91 and is vertically movable relative to the intermediate bearing ring 91. The spherical bearing 85 shown in FIG. 16 is the same as the spherical bearing 85 shown in FIG. 14 in that the fulcrum O, which is the center of the tilting movement, is on a central axis of the retainer ring 40, but differs in that the fulcrum O shown in FIG. 16 is located at a position lower than the fulcrum O shown in FIG. 14. The spherical bearing 85 shown in FIG. 16 can provide the fulcrum O at the same height of the surface of the polishing pad 2 or lower than the surface of the polishing pad 2.

FIG. 18A is a cross-sectional view of the drive ring 81 and the retainer ring 40 shown in FIG. 12. FIG. 18B is a bottom view showing a part of the drive ring 81 shown in FIG. 12. A plurality of holes 124 are formed in the retainer ring 40 along its circumferential direction (only one hole 124 is shown in FIG. 18A). More specifically, these holes 124 are formed in the upper surface 40b of the retainer ring 40. A plurality of reinforcing pins 82, which are made of stainless steel and connectable to the retainer ring 40, are fixed to a lower portion of the drive ring 81. These reinforcing pins 82 are arranged apart from each other along the circumferential direction. Each of the reinforcing pins 82 is inserted into each of the holes 124 of the retainer ring 40. The strength of the retainer ring 40 is reinforced by the reinforcing pins 82. The configuration of the embodiment described with reference to FIGS. 18A and 18B can be applied to each of the embodiments described with reference to FIGS. 1 through 10.

The flatness of the contact surface 81a of the drive ring 81 in the circumferential direction in each of the above-described embodiments is as flat as 4.6 μm, so that non-uniformity of the pressure in the circumferential direction applied from the retainer ring 40 to the polishing pad 2 can be suppressed. As a result, the polishing head 1 can suppress the variation in the polishing rate of the wafer W in its circumferential direction.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### INDUSTRIAL APPLICABILITY

The present invention is applicable to a substrate holding apparatus used to polish a surface of a substrate by pressing the substrate against a polishing tool, such as a polishing pad. Further, the present invention is applicable to a method of manufacturing a drive ring used in the substrate holding apparatus.

### REFERENCE SIGNS LIST

1 polishing head
2 polishing pad
2a polishing surface
3 polishing table
3a table shaft
5 polishing liquid supply nozzle
7 film-thickness sensor
9 polishing controller
10 polishing head body
11 polishing head shaft
12 rotary cylinder
13 motor
14 timing pulley
16 polishing head oscillation arm
18 polishing head motor
19 timing belt
20 timing pulley
21 support shaft
25 rotary joint
26 bearing
27 vertically moving mechanism
28 bridge
29 support base
30 pillar
32 ball screw
32a screw shaft
32b nut
38 servomotor
40 retainer ring
40a lower surface
40b upper surface
40c threaded hole
41 flange
42 spacer
43 carrier
45 elastic membrane
50, 51, 52, 53 pressure chamber
60 retainer ring pressing mechanism
61 piston
62 rolling diaphragm
63 retainer ring pressure chamber
75 coupling member
76 shaft portion
77 hub
78 spoke
79 screw
80 drive pin
81 drive ring
81a contact surface
81b inner area
81c outer area
81d intermediate area
81f through-hole
82 reinforcing pin
84 bolt
85 spherical bearing
88 through-hole
91 intermediate bearing ring
92, 102 outer bearing ring
93, 101 inner bearing ring
124 hole

What is claimed is:

1. A substrate holding apparatus comprising:
a polishing head body;
a drive ring disposed below the polishing head body; and
a retainer ring fixed to the drive ring,
wherein the drive ring has an annular contact surface that contacts the retainer ring,
the contact surface has a flatness of not more than 4.6 μm in a circumferential direction of the contact surface, and
the flatness represents a difference in a height between a highest position and a lowest position of the contact surface.

2. The substrate holding apparatus according to claim 1, wherein an inner area of the contact surface has a flatness of not more than 4.6 μm in the circumferential direction of the contact surface, and the inner area is an area including an innermost edge of the contact surface.

3. The substrate holding apparatus according to claim 1, wherein an outer area of the contact surface has a flatness of not more than 4.6 μm in the circumferential direction of the contact surface, and the outer area is an area including an outermost edge of the contact surface.

4. The substrate holding apparatus according to claim 1, wherein an intermediate area of the contact surface has a flatness of not more than 4.6 μm in the circumferential direction of the contact surface, and the intermediate area is located radially outwardly of an innermost edge of the contact surface and radially inwardly of an outermost edge of the contact surface.

5. The substrate holding apparatus according to claim 1, further comprising reinforcing pins inserted into the retainer ring and fixed to a lower portion of the drive ring, the reinforcing pins being arranged apart from each other along the circumferential direction.

6. The substrate holding apparatus according to claim 1, further comprising spherical bearing configured to tiltably support the drive ring and the retainer ring.

7. The substrate holding apparatus according to claim 1, wherein a rigidity of the drive ring is greater than a rigidity of the retainer ring.

8. A method of manufacturing a drive ring used in a substrate holding apparatus configured to press a substrate against a polishing pad, comprising:
polishing a contact surface of the drive ring such that a flatness of the contact surface in a circumferential direction is not more than 4.6 μm,
wherein the contact surface is an annular contact surface that contacts the retainer ring used in the substrate holding apparatus, and
the flatness represents a difference in a height between a highest position and a lowest position of the contact surface.

9. The method according to claim 8, wherein polishing the contact surface such that the flatness is not more than 4.6 μm comprises:
grinding the contact surface of the drive ring; and then
polishing the contact surface until the flatness becomes 4.6 μm or less by relatively moving the drive ring and a polishing tool while pressing the contact surface against the polishing tool in the presence of abrasive grains between the drive ring and the polishing tool.
